(19) United States
(12) Patent Application Publication
(10) Pub. No.: US 2013/0233602 A1
(43) Pub. Date: Sep. 12, 2013

(54) SURFACE TREATMENT STRUCTURE OF CIRCUIT PATTERN

(71) Applicants: Ting-Hao Lin, Taipei (TW); Yu-Hui Wu, Kaohsiung (TW)

(72) Inventors: Ting-Hao Lin, Taipei (TW); Yu-Hui Wu, Kaohsiung (TW)

(21) Appl. No.: 13/416,158

(22) Filed: Mar. 9, 2012

(51) Int. Cl. H05K 1/09

(52) U.S. Cl. 174/257

(57) ABSTRACT

A surface treatment structure formed on a circuit pattern on a printed circuit board is provided, which includes a first gold layer, a palladium layer, and a second gold layer stacked from bottom to top, respectively, or includes a palladium layer, and a second gold layer stacked from bottom to top, respectively. The palladium layer is used to prevent the diffusion of the copper ions from the circuit pattern. Only a thin surface treatment structure of the circuit pattern of the present invention is required to achieve excellent wire bonding, so that the overall thickness is reduced, and the manufacture cost is also reduced. Furthermore, the uniformness of palladium is better than that of nickel, and thereby the surface treatment structure of the circuit pattern of the present invention is suitably used for manufacturing the fine-line circuits, thereby having a wider industrial applicability.

### BACKGROUND OF THE INVENTION

1. Field of the Invention

The present invention relates to a surface treatment structure of a circuit pattern, and more particularly to a thin surface treatment structure including a palladium layer, by which the problems occurred in conventional arts can be reduced.

2. The Prior Arts

After a circuit pattern is formed on a printed circuit substrate, the gold wires used as the soldering wires are often wire-bonded to the circuit pattern which is usually made of copper or aluminum, and however, such a wire bonding is affected by the materials used. FIG. 1 is a cross sectional view of a conventional surface treatment structure of circuit pattern. The conventional surface treatment structure 30 is formed on a circuit pattern 10 formed on a printed circuit substrate 100, and the circuit pattern 10 is usually a copper bump. The surface treatment structure of circuit pattern 30 includes a nickel layer 31 and a gold layer 33, and the strength of wire bonding can be enhanced by using the same gold material for the gold layer 33 and the gold soldering wires, and the nickel layer 31 is mainly used to prevent the diffusion of the copper ions from the circuit pattern 10 into the gold layer 33, so as to avoid the wiring bonding from being affected.

However, with the advances of technology, the demand for high precision of wire width and wire thickness is increased. Conventionally, a thickness of a nickel layer is about 5 μm, and a thickness of a gold layer is about 0.5 μm, and thereby the thickness of a circuit is increased, which limits the circuit density. Furthermore, when the price of gold increases, the manufacture cost becomes higher as the thickness of the gold layer increases. Additionally, due to a characteristic of nickel, the thickness of nickel is not uniform, which may cause the lowerness of line pitch, and short circuit when applied the surface treatment structure in the fine-line circuits.

Therefore, there is a need for providing a surface treatment structure of a circuit pattern, which can reduce the manufacture cost, increase the circuit density, and overcome the various problems in the conventional techniques.

### SUMMARY OF THE INVENTION

An objective of the present invention is to provide a surface treatment structure formed on a circuit pattern on a printed circuit board. The circuit pattern is usually a copper circuit. The surface treatment structure formed on a circuit pattern includes a first gold layer, a palladium layer and a second gold layer stacked from bottom to top, respectively, or includes a palladium layer, and a second gold layer stacked from bottom to top, respectively. The thickness of the first gold layer is between 0.01 μm and 0.1 μm, and the thickness of the palladium layer is between 0.03 μm and 0.15 μm, and the thickness of the second gold layer is between 0.03 μm and 0.15 μm.

In the present invention, the palladium layer is used to effectively prevent the diffusion of the copper ions from the circuit pattern into the outer layer, so that the strength of wire bonding and tin balls soldering can be enhanced. Only a thin surface treatment structure of the circuit pattern of the present invention is required to achieve excellent wire bonding, so that an overall thickness can be reduced and the manufacture cost is also reduced. Furthermore, the uniformness of the surface treatment structure is improved. Therefore, the surface treatment structure of the circuit pattern of the present invention is suitably used for manufacturing the fine-line circuits, thereby having a wider industrial applicability.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a cross sectional view of a surface treatment structure of a circuit pattern according to the prior art;

FIG. 2 is a cross sectional view of a surface treatment structure of a circuit pattern according to the first embodiment of the present invention; and

FIG. 3 is a cross sectional view of a surface treatment structure of a circuit pattern according to the second embodiment of the present invention.

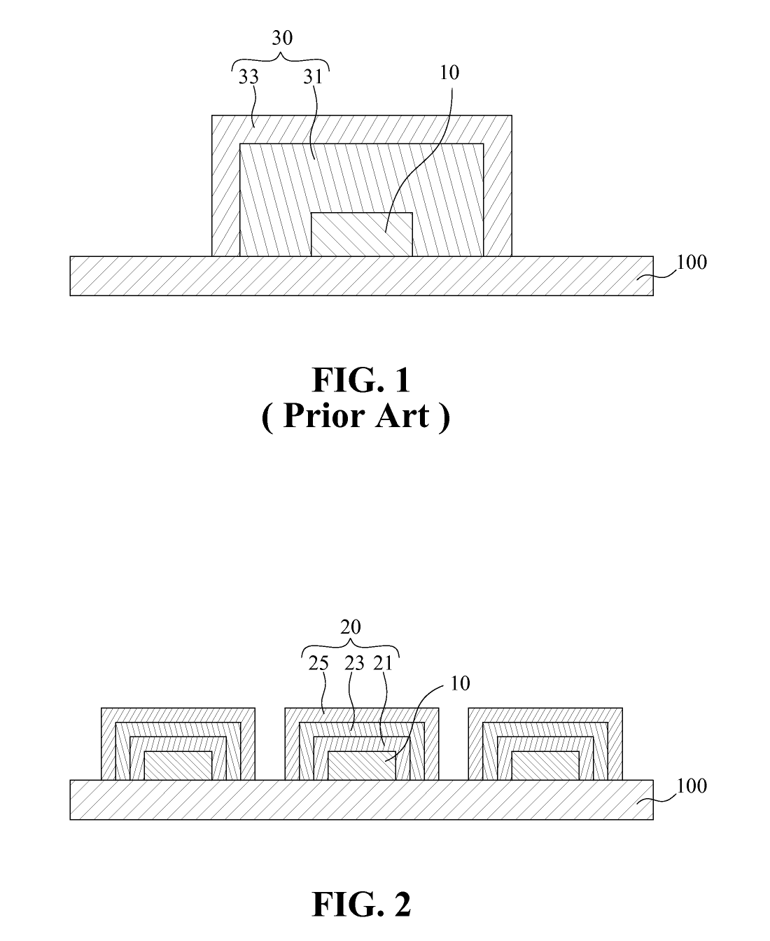

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

FIG. 2 is a cross sectional view of a surface treatment structure of a circuit pattern according to the first embodiment of the present invention. Referring to FIG. 2, a surface treatment structure 20 is formed on a circuit pattern 10 which is formed on a printed circuit board 100. The circuit pattern 10 is usually the copper circuit. The surface treatment structure 20 formed on the circuit pattern 20 includes a first gold layer 21, a palladium layer 23 and a second gold layer 25 stacked from bottom to top, respectively. The thickness of the first gold layer is between 0.01 μm and 0.1 μm, and the thickness of the palladium layer is between 0.03 μm and 0.15 μm, and the thickness of the second gold layer is between 0.03 μm and 0.15 μm. The first gold layer 21, the palladium layer 23, and the second gold layer 25 are formed by electroplating, electroless plating, evaporation or sputtering method.

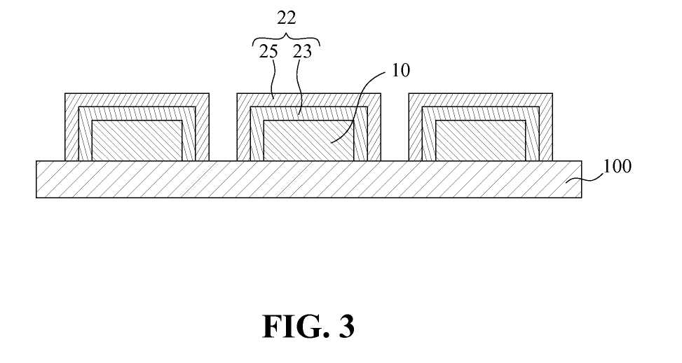

FIG. 3 is a cross sectional view of a surface treatment structure of a circuit pattern according to the second embodiment of the present invention. The surface treatment structure 22 in the second embodiment is the same as that in the first embodiment except that the surface treatment structure 22 only includes a palladium layer 23, and a second gold layer 25 stacked from bottom to top, respectively. The thickness of the palladium layer is between 0.03 μm and 0.15 μm, and the thickness of the second gold layer is between 0.03 μm and 0.15 μm. The palladium layer 23 and the second gold layer 25 are formed by electroplating, electroless plating, evaporation or sputtering method.

In the present invention, the palladium layer is used to effectively prevent the diffusion of the copper ions from the circuit pattern into the outer layer, so that the strength of wire bonding can be enhanced. Only a thin surface treatment structure of the circuit pattern of the present invention is required to achieve excellent wire bonding, so that an overall thickness can be reduced and the manufacture cost is also reduced. Furthermore, the uniformness of the surface treatment structure is improved. Therefore, the surface treatment structure of the circuit pattern of the present invention is suitably used for manufacturing the fine-line circuits, thereby having a wider industrial applicability.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A surface treatment structure formed on a circuit pattern on a printed circuit board, comprising:
a first gold layer formed on the circuit pattern, a thickness of the first gold layer being between 0.01 μm and 0.1 μm;
a palladium layer stacked on the first gold layer, a thickness of the palladium layer being between 0.03 μm and 0.15 μm; and
a second gold layer stacked on the palladium layer, a thickness of the second gold layer being between 0.03 μm and 0.15 μm.

2. The surface treatment structure as claimed in claim 1, wherein the first gold layer, the palladium layer and the second gold layer are formed by at least one of electroplating, electroless plating, evaporation, and sputtering methods.

3. A surface treatment structure formed on a circuit pattern on a printed circuit board, comprising:
a palladium layer stacked on the circuit pattern, a thickness of the palladium layer being between 0.03 μm and 0.15 μm; and
a second gold layer stacked on the palladium layer, a thickness of the second gold layer being between 0.03 μm and 0.15 μm.

4. The surface treatment structure as claimed in claim 3, wherein the palladium layer and the second gold layer are formed by at least one of electroplating, electroless plating, evaporation, and sputtering methods.
